(19) United States
(12) Patent Application Publication
(10) Pub. No.: US 2003/0063026 A1
(43) Pub. Date: Apr. 3, 2003

(54) Switched-capacitor based charge redistribution successive approximation analog to digital converter (ADC)

(75) Inventor: Tapas Nandy, Delhi (IN)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: STMicroelectronics Pvt. Ltd., Noida (IN)

(21) Appl. No.: 10/255,153

(22) Filed: Sep. 25, 2002

(30) Foreign Application Priority Data
Sep. 28, 2001 (IN) 1005/DEL/2001

(51) Int. Cl. H03M 1/12

(52) U.S. Cl. 341/172

(57) ABSTRACT

An improved binary-weighted, switched-capacitor, charge-redistribution successive approximation analog-to-digital converter (ADC) may include an adjusting mechanism for adding a charge corresponding to one-half of the least significant bit (LSB) of the ADC to the charge stored in a switched capacitor array thereof after the sampling phase of the ADC. This is done to provide a quantization error that is evenly distributed between ±0.5 times the LSB, without the need for any additional processing clock cycles.

### FIELD OF THE INVENTION

The invention relates to the field of electronic devices, and, more particularly, to analog-to-digital converters (ADC) and related methods.

### BACKGROUND OF THE INVENTION

Analog-to-digital converters (ADCs) are used to convert analog signals to a digital representation thereof. The resolution of the conversion is determined by the number of bits provided in the digital output of the ADC, and the accuracy is defined by the output's deviation from the true value of the analog input signals.

An ideal ADC transfer characteristic is illustrated in FIG. 1(a), in which straight line 1.1 corresponds to the analog input or an ideal, infinite resolution ADC, while the staircase waveform 1.2 is the output of an ideal finite resolution ADC. The deviation of the stepped waveform 1.2 from the analog input is the quantization error 1.3 of the ADC, which is illustratively shown in FIG. 1(b) to be varying between ±0.5 times the value of the least signification bit (LSB).

Referring now to FIGS. 2(a) and 2(b), the transfer characteristic 2.2 and quantization error 2.3 of a switched-capacitor charge redistribution successive approximation ADC according to the prior art are shown, respectively. It may be seen that the transfer characteristic 2.2 is shifted with respect to the true value 2.1, resulting in the quantization error 2.3 that varies between 0 and −1.0 times the LSB. This asymmetrical error distribution is undesirable as it reduces the error margins for other components, which results in increased effective error.

Certain attempts have been made in the prior art to address overall error correction problems. By way of example, U.S. Pat. No. 4,399,426 describes a self-calibrating successive approximation register ADC which uses redundant switched-capacitor arrays, successive approximation registers and logic together with a memory that includes correction data that is added to the normal output to compensate for the error. This technique is designed to adjust for individual capacitor mismatches in the binary-weighted switched capacitor network, but it does not actually address the asymmetrical quantization error problem. Moreover, this technique is expensive in terms of circuit size and conversion time.

U.S. Pat. Nos. 4,451,821; 4,999,633; and 5,684,487 similarly disclose techniques which address the errors arising from individual capacitor value deviations in the switched-capacitor network. These patents also do not address the asymmetrical quantization error issue. Additionally, U.S. Pat. No. 4,975,700 provides one approach for correcting linear and quadratic error terms arising from capacitor value dependence and applied voltage. Yet, this approach also does not address asymmetrical quantization error issues.

Furthermore, U.S. Pat. No. 5,852,415 addresses the problem of correcting for gain and input offset errors, including quantization error misalignment. However, the technique described therein requires a trimmable capacitor array, array switches, a digital controller and additional calibration steps that result in significant overhead in circuit size and conversion time, on top of a separate calibration phase.

### SUMMARY OF THE INVENTION

An object of the present invention is to provide a switched capacitor, charge redistribution successive approximation register analog-to-digital converter (ADC) with a quantization error that is evenly distributed between ±0.5 times the value of the LSB, and without significant increase in size and with substantially no increase in conversion time.

This and other objects, features, and advantages in accordance with the present invention are provided by a binary-weighted, switched-capacitor, charge-redistribution successive approximation ADC which may include an adjusting mechanism for adding a charge corresponding to one-half of the least significant bit (LSB) of the ADC to the charge stored in the switched capacitor array during the sampling phase of the ADC. This is done to provide a quantization error that is evenly distributed between 0.5 times the value of the LSB, without the need for any additional processing clock cycles.

More particularly, the adjusting mechanism may include an adjusting capacitor with a value equal to one-half of the LSB capacitor in the binary weighted switched capacitor array. The adjusting capacitor may be connected at one terminal to the common terminal of the capacitor array, and connected at the other terminal to a connection means or circuit. The connection circuit may connect this other terminal to a higher reference voltage during the sampling phase and to a lower reference voltage during the hold and conversion phases. The difference between the higher reference voltage and the lower reference voltage may be such that the charge injected by the adjusting capacitor after the sampling phase corresponds to one-half the LSB of the ADC.

In addition, the ADC may use the switched capacitor network for generating all of the output bits. In this case, the higher reference voltage may be the voltage applied to the capacitors in the switched capacitor network during the conversion phase, and the lower reference voltage may be the voltage applied to the capacitors in the switched-capacitor network in the hold phase.

Alternately, the ADC may use the switched capacitor network for generating the more significant outputs bits and use a multi-tap resistor divider network for generating the lesser significant output bits. In this case, the higher reference voltage and the lower reference voltage may be selected from the voltages available from the multi-tap resistor divider network such that the voltage difference provided thereby along with that of the adjusting capacitor adds a charge to the switched capacitor array corresponding to one-half the least significant output bit of the ADC.

The above-described ADC may be implemented in a single integrated circuit in which the addition of the adjusting capacitor and the connecting circuit advantageously result in only minimal increase in chip area. By way of example, the connection circuit may be a two-way switch. In addition, the lower reference voltage may be ground for the case of a unipolar supply ADC, and the lower reference voltage may be a negative reference voltage for the case of a bipolar supply ADC.

### BRIEF DESCRIPTION OF THE DRAWINGS

The invention will now be described with reference to the accompanying drawings, in which:

FIG. 1(a) is a graph illustrating ideal ADC transfer characteristics;

FIG. 1(b) is a graph illustrating an ideal ADC quantization error;

FIG. 2(a) is a graph illustrating the transfer characteristic of a switched-capacitor successive approximation ADC according to the prior art;

FIG. 2(b) is a graph illustrating the quantization error of a switched-capacitor, successive approximation ADC according to the prior art;

FIG. 3 is a schematic circuit diagram of a switched-capacitor successive approximation ADC according to the prior art;

FIG. 4 is a schematic circuit diagram of a switched-capacitor successive approximation ADC according to the present invention; and

FIG. 5 is a schematic circuit diagram of a hybrid successive approximation ADC according to the invention that uses a switched capacitor network for the more significant bits and multi-tap resistor divider network for the less significant bits.

### DETAILED DESCRIPTION OF THE PREFERRED EMBODIMENTS

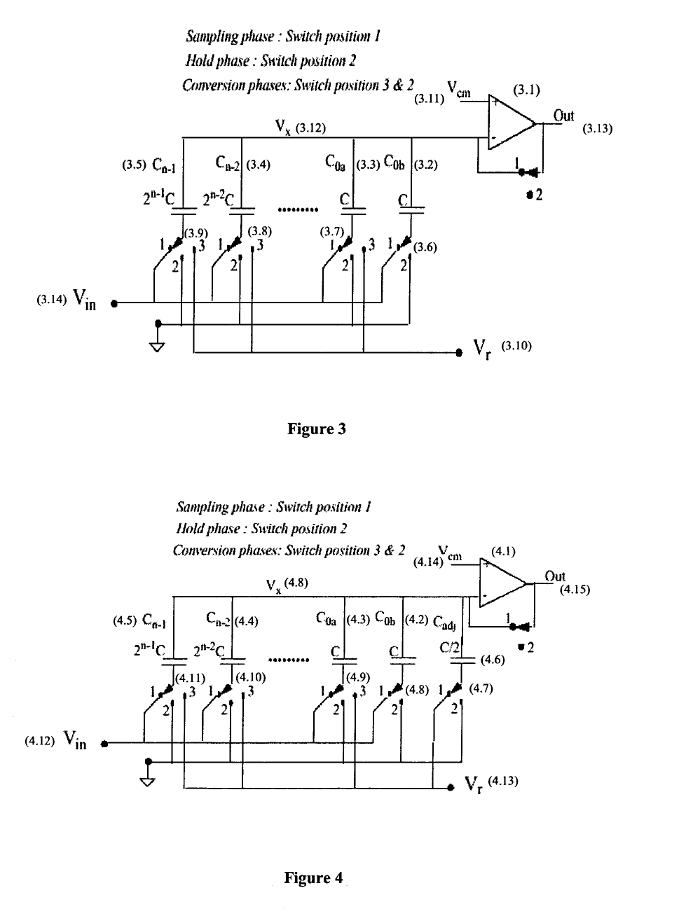

Turning now to FIG. 3, a switched capacitor, successive approximation ADC according to prior art is illustratively shown (the control logic and successive approximation register thereof are not shown for clarity of illustration). Such an ADC has a quantization error varying between 0 and −1 times the LSB in theory, resulting in a transfer characteristic which is offset by −0.5 times the LSB from the ideal ADC characteristic, as noted above.

The binary weighted capacitors 3.2-3.5, or C_{0b} through Cₙ₋₁, have a unit capacitor value C. The positions 1-3 associated with switches 3.6 through 3.9 correspond to different phases of the conversion process. The present example assumes a single supply voltage and single reference voltage (Vᵣ) ADC for clarity of illustration, but the present invention is equally applicable to a dual-supply, dual-reference voltage circuit as well. The input 3.11 (V_{cm}) to the comparator 3.1 is usually set to one-half Vᵣ or one-half the supply. The offset voltage V_{off} of the comparator 3.1 is stored at the top plate of the capacitor bank during the sampling phase. The converted digital outputs are coded as bᵢ (I=n−1 to 0).

During a sampling phase (which corresponds to the switches 3.6 to 3.9 being in the switch position 1), the voltage and the charge at the top plate of the capacitor bank are given by:

Vₓ=V_{cm}+V_{off}, and (1)

Qₓ=−(Vᵢₙ−V_{cm}−V_{off})·2ⁿC. (2)

During a hold phase (which corresponds to the switches 3.6 to 3.9 being in the switch position 2), the top plate voltage is given by the charge (which does not escape as the top plate switch opens prior to the hold phase) divided by the total bank capacitors (2ⁿ·C.), that is:

Vₓ=−(Vᵢₙ−V_{cm}−V_{off}). (3)

Furthermore, during the conversion phase the bottom plate switches 3.3 (for the LSB, bo) through 3.5 (for the MSB, bₙ₋₁) (i.e., corresponding to C₀ₐ through Cₙ₋₁) are thrown back and forth between position 3 (Vᵣ) and position 2 (ground) successively, starting from the MSB, and the switch 3.6 for capacitor 3.2 (C_{0b}) remains in position 2. The input 3.12 (i.e., Vₓ) to the comparator 3.1 gets modulated as per the following equation:

$${V}_{x} = ( {V}_{c m} + {V}_{off} ) - {V}_{i n} + {V}_{r} \cdot [ {\sum }_{i = n - 1}^{0} \frac{{b}_{i}}{{2}^{n - 1}} ] . \qquad ( 4 )$$

The third term in the right hand side of equation (4) gives Vₒᵤₜ, the voltage equivalent of the converted digital code. If the comparator output is 1_{b} (where the subscript b stands for binary notation), Vᵢₙ is more than Vₒᵤₜ, so bᵢ is set to 1_{b} and the switch in question is kept at Vᵣ. On the other hand, if the comparator output is 0_{b}, bᵢ is reset and the switch in question is returned to ground.

Now, assuming the input 3.14 (Vᵢₙ) is around 1 LSB, i.e., Vᵣ/2′, then all conversion phases for higher order bits bₙ₋₁ to b₁ are reset to ₀_{b}, and b₀ is evaluated by temporarily setting it to 1_{b} and connecting C₀ₐ's bottom plate 3.3 (C₀ₐ) to Vᵣ. The last two terms of the right hand side of the equation (4), namely

$$( - {V}_{i n} + {V}_{r} \cdot [ {\sum }_{i = n - 1}^{0} \frac{{b}_{i}}{{2}^{n - i}} ] ) ,$$

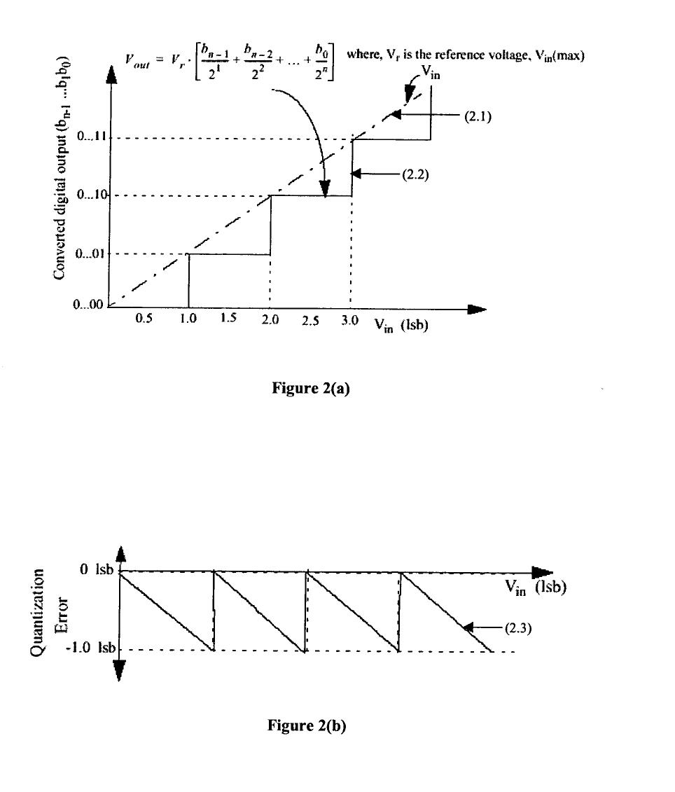

are positive as long as Vᵢₙ is less than 1 LSB, and Vₓ is more than V_{cm+V}_{off}, hence the comparator output is 0_{b} and b₀ is reset. As such, the digital output is 00 . . . 0_{b}, which is equivalent to Vₒᵤₜ=0, and the digital output becomes 00 . . . 1_{b} only when Vᵢₙ>1 LSB. Similarly, the digital output increments only when Vᵢₙ is greater than 1 LSB, 2 LSB, 3 LSB, etc. and the quantization noise varies from 0 to −1 LSB, as shown in FIG. 2(b).

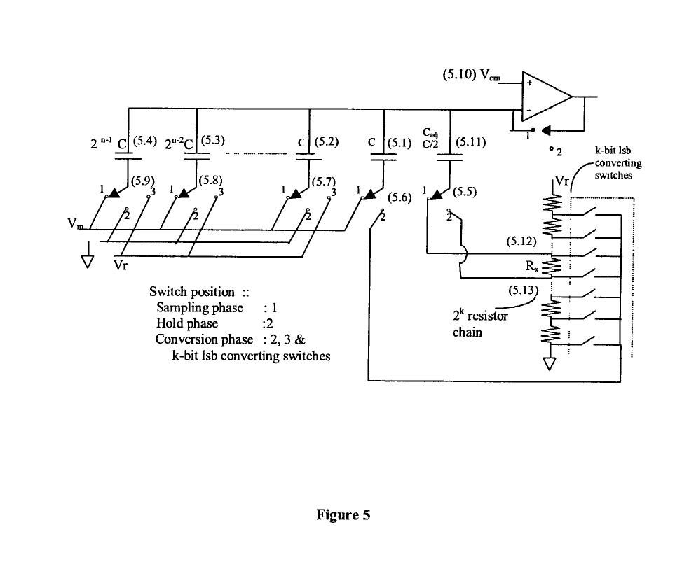

A switched-capacitor ADC in accordance with the invention is now described with reference to FIG. 4. An extra capacitor 4.6 (or C_{adj}) of a value C/2 is added to the bank of capacitors. Thus, the total capacitance of the bank becomes (2ⁿ+1)·C. During the sampling phase (i.e., switch position 1), the bottom plate of the capacitor 4.6 (C_{adj}) is connected to the output 4.13 (Vᵣ), and during hold and conversion phases its bottom plate is held at ground. The top plate charge of the capacitor bank during sampling phase is:

$$Qx = - ( {V}_{i n} - {V}_{c m} - {v}_{off} ) \cdot {2}^{n} \cdot C - ( {V}_{r} - {V}_{c m} - {v}_{off} ) \cdot \frac{C}{2} , \qquad ( 5 )$$

and the top plate voltage during hold phase is:

$${V}_{x} = - ( {V}_{i n} - {V}_{c m} - {v}_{off} ) \cdot \frac{{2}^{n}}{{2}^{n} + \frac{1}{2}} - ( {V}_{r} - {V}_{c m} - {v}_{off} ) \cdot \frac{\frac{1}{2}}{{2}^{n} + \frac{1}{2}} , \qquad ( 6 )$$

Similarly, during the conversion phase, the top plate voltage gets modulated. More particularly, the bottom plate switches 4.9-4.11 for the capacitors 4.3-4.5 (i.e., C₀ₐ through Cₙ₋₁) switch between position 3 and 2, and the switches 4.7 and 4.8 for the capacitors 4.6 and 4.2 (i.e., C_{adj} & C_{0b}) remain in position 2, that is:

$$\begin{matrix}{V}_{x} = - ( {V}_{i n} - {V}_{c m} - {v}_{off} ) \cdot \frac{{2}^{n}}{( {2}^{n} + \frac{1}{2} )} - ( {V}_{r} - {V}_{c m} - {v}_{off} ) \cdot \\ \frac{\frac{1}{2}}{( {2}^{n} + \frac{1}{2} )} + {V}_{r} \cdot \frac{{2}^{n}}{( {2}^{n} + \frac{1}{2} )} \cdot [ {\sum }_{i = n - 1}^{0} \frac{{b}_{i}}{{2}^{n - i}} ] \\ = ( {V}_{c m} + {V}_{off} ) - ( {V}_{i n} \cdot \frac{{2}^{n}}{( {2}^{n} + \frac{1}{2} )} ) - ( {V}_{r} \cdot \frac{\frac{1}{2}}{( {2}^{n} + \frac{1}{2} )} ) + \\ {V}_{r} \cdot \frac{{2}^{n}}{( {2}^{n} + \frac{1}{2} )} \cdot [ {\sum }_{i = n - 1}^{0} \frac{{b}_{i}}{{2}^{n - i}} ] .\end{matrix} \qquad ( 7 )$$

When the input 4.12 (Vᵢₙ) is around 0.5 LSB, i.e., ½·Vᵣ/2ₙ, bₙ₋₁ through b₁ are reset to 0_{b}, and b₀ is evaluated by temporarily setting it to 1_{b} and connecting the bottom plate of capacitor 4.3 (i.e., C₀ₐ) to Vᵣ. The last three terms of equation (7) then become:

$$- {V}_{r} \cdot \frac{\frac{1}{2}}{( {2}^{n} + \frac{1}{2} )} - {V}_{r} \cdot \frac{\frac{1}{2}}{( {2}^{n} + \frac{1}{2} )} + {V}_{r} \cdot \frac{1}{( {2}^{n} + \frac{1}{2} )} ,$$

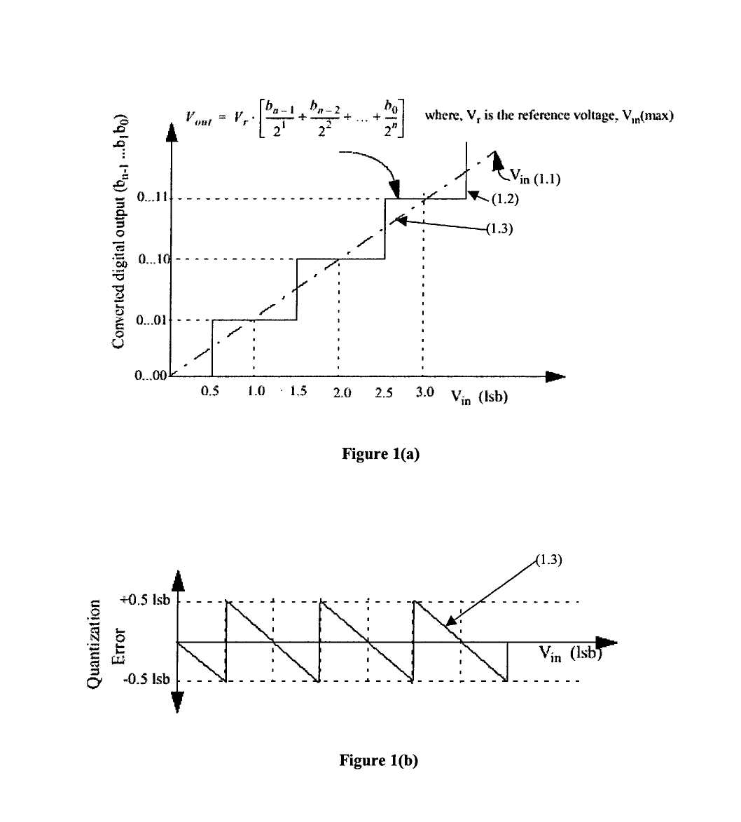

and are negative the moment Vᵢₙ is more than 0.5 LSB. Hence, the input 4.16 (Vₓ) becomes less than V_{cm}+V_{off}, and the comparator output 4.15 becomes 1_{b}, b₀ is set to 1_{b}, and Dₒᵤₜ=00.1_{b} and remains in this state until Vᵢₙ<1.5 LSB. This analysis can be extended to other bits' evaluation, in which case it will be found that the digital output increments at 0.5, 1.5, 2.5 etc., LSB of Vᵢₙ. Now, it will be appreciated that Vₒᵤₜ−Vᵢₙ, the quantization error, varies between ±0.5 LSB, as in the case of ideal ADC (see FIG. 1(b)).

Referring now additionally to FIG. 5, an application of the above described technique to an ADC using a hybrid of switched capacitor and multi-tap resistor divider network is now described. Here, the lower k-bits of an M-bit ADC are determined by the resistive divider chain, where M=n+k. In this case, the 3^{rd} term of equation (7), i.e.,

$$( {V}_{r} \cdot \frac{\frac{1}{2}}{( {2}^{n} + \frac{1}{2} )} ) ,$$

does not represent a half-LSB addition to Vᵢₙ. During sampling (switch position 1), the bottom plate of the capacitor 5.11 (C_{adj}) is connected to the upper tap-point 5.12 of any resistor segment Rₓ in the resistor divider chain. After sampling, during the hold and conversion phase (switch position 2), the bottom plate of the capacitor 5.11 (C_{adj}) is connected to the lower tap-point 5.13 of the same resistor Rₓ. The voltage difference at these two tap-points is Vᵣ/2^{k}, and the 3^{rd} term of equation (7) then gets modified to

$$( \frac{{V}_{r}}{{2}^{k}} \cdot \frac{\frac{1}{2}}{( {2}^{n} + \frac{1}{2} )} ) ,$$

and the value is thus equivalent to a half-LSB of an M bit conversion (where M=n+k), which value is added to Vᵢₙ. Hence, the ADC's transfer curve gets aligned to the ideal characteristic in this as well.

Based upon the foregoing, those of skill in the art will appreciate several advantages provided by the present invention. For example, the present invention provides the designer with a ±0.5 LSB margin for circuit component inaccuracies, which is beneficial if the designer wants a ±1 LSB error margin in the ADC design. More particularly, if it is assumed that the matching accuracy of the binary weighted capacitors are perfect, comparator resolution can be relaxed to 0.5 LSB. Alternatively, if the comparator is assumed to be perfectly accurate, the capacitor Cₙ₋₁ can have a mismatch of 100/2ⁿ⁻¹ percent from the rest of the bank, and so on. Thus, a practical choice would be a mix of both.

Moreover, in accordance with the present invention there is no extra clock cycle needed during sampling/conversion phases. Furthermore, the ADC's converted output would ideally have no offset error and saturate at Vᵢₙ, which is 1.5 LSB below Vᵣ and the same as the ideal case. This effect is called the ADC over-loading. The reduction in each LSB step, due to scaling down of the Vₓ swing, is [2ⁿ/(2ₙ+½)] times less than the circuit without the capacitor C_{adj}, so the resolution of the comparator should preferably be better. For a 10-bit ADC, this demand is just 0.05% more compared to not having the capacitor C_{adj}.

That which is claimed is:

1. An improved binary-weighted, switched-capacitor, charge-redistribution successive approximation analog-to-digital converter (ADC) characterized in that it includes an adjusting mechanism for adding a charge corresponding to one-half of the least significant bit (LSB) of said ADC to the charge stored in the switched capacitor array after the sampling phase of said ADC so as to provide a quantization error that is evenly distributed between +0.5 LSB and −0.5 LSB, without the need for any additional processing clock cycles.

2. An improved analog-to-digital converter (ADC) as claimed in claim 1 wherein said adjusting mechanism comprises an adjusting capacitor with a value equal to one-half of the LSB capacitor in said binary weighted switched capacitor array connected at one end to the common terminal of said capacitor array and at the other end to a connection means that connects it to a higher reference voltage during the sampling phase and to a lower reference voltage during the hold phase and conversion phase, the difference between said higher reference voltage and said lower reference voltage being such that the charge injected by said adjusting capacitor onto said binary weighted switched capacitor array after the sampling phase corresponds to one-half of the LSB value of said ADC.

3. An improved analog-to-digital converter (ADC) as claimed in claim 2 said ADC using said switched-capacitor network for generating all output bits, wherein said higher reference voltage is the higher reference voltage applied to the capacitors in said switched-capacitor network during the conversion phase and said lower reference voltage is the lower reference voltage applied to said capacitors in switched-capacitor network in the conversion phase.

4. An improved analog-to-digital converter (ADC) as claimed in claim 2 said ADC using said switched capacitor network for generating the more significant outputs bits and using a multi-tap resistor divider network for generating the lesser significant output bits, wherein said higher reference voltage and said lower reference voltage are selected from the voltages available from said multi-tap resistor divider network such that the voltage difference along with said adjusting capacitor adds a charge to said switched capacitor array corresponding to one-half of the least significant output bit from said ADC.

5. An improved analog-to-digital converter (ADC) as claimed in claim 2 implemented in a single integrated circuit wherein addition of said adjusting capacitor and said connecting means, results in minimal increase in chip area.

6. An improved analog-to-digital converter (ADC) as claimed in claim 2 wherein said connection means is a two-way switch.

7. An improved analog-to-digital converter (ADC) as claimed in claim 2 wherein said lower reference voltage is ground for the case of a unipolar supply ADC.

8. An improved analog-to-digital converter (ADC) as claimed in claim 2 wherein said lower reference voltage is a negative reference voltage for the case of bipolar supply ADC.
